(19) United States
(12) Patent Application Publication
(10) Pub. No.: US 2016/0254176 A1
(43) Pub. Date: Sep. 1, 2016

(54) Positive Pressure Bernoulli Wand with Coiled Path

(71) Applicant: AZSimilate, LLC, Tempe, AZ (US)

(72) Inventors: Eric Shawn Monaco, Tempe, AZ (US); William Edward Chel Frans, Tempe, AZ (US); Scott Thomas Yee, Phoenix, AZ (US)

(73) Assignee: AZSimilate, LLC, Tempe, AZ (US)

(21) Appl. No.: 15/055,607

(22) Filed: Feb. 28, 2016

Related U.S. Application Data
(60) Provisional application No. 62/121,573, filed on Feb. 27, 2015.

(51) Int. Cl. H01L 21/683; B25J 15/06

(52) U.S. Cl. CPC H01L 21/6838; B25J 15/0616

(57) ABSTRACT

A wand operating under the Bernoulli principle to pick up, transport and deposit wafers, which continuous pattern imposed into the horizontal surface of the single piece paddle, a variety of openings oriented within the continuous pattern and passing through the horizontal surface of the single piece paddle, a channel with walls having a variety of openings spaced apart from one another and passing through the walls of channel, which may be fit into the continuous pattern and the openings in the walls of channel aligning to some of the variety of openings oriented within the continuous pattern.

### REFERENCE TO RELATED APPLICATIONS

This application claims the benefit of provisional application 62/121,573, filed on Feb. 27, 2015, the entire contents of which are incorporated by this reference.

### BACKGROUND

Various systems are known within the semiconductor industry for handling wafers during the processing of fragile semi-conductor material. One type of devices is known as the Bernoulli wand typically used for high-temperature, touch-free applications. Bernoulli wands utilize jets of gas downward from the wand toward the wafer to create a region of low pressure above the wafer, therefore lifting it without damaging the wafer material.

The design of the channel for the flow of the working gas within the wand is commonly created by multiple channels that intersect and are formed at angles to each other. The fabrication of these channels may create stress points within the quartz substrate at the intersection of channels. Stress points may also be formed in a single channel in any region where one or more sidewalls of a channel form a step, which is seen as an angle between two common surfaces. Upon the application of the working gas or upon experiencing a significant temperature change, these stress points may result in small fractures which may propagate and ultimately destroy the wand. Prior Art wands are typically used around 400 degrees C. to 1200 degrees C.

What is needed is a Bernoulli wand construction that resists this failure mode.

### BRIEF SUMMARY

The present invention has several embodiments. One embodiment provides a Bernoulli wand useful for transporting semiconductor wafers during manufacturing of integrated circuits. These wands are especially useful for transporting or manipulating the wafers when the processing steps cause the wafer to have a high temperature.

In some embodiments, the wand has top and bottom plates. The underside of the top plated contains several small gas orifices penetrating through the bottom plate emerging inside of a curved channel created in or on the upper surface of the bottom plate. In some embodiments, the small gas orifices have a diameter of 0.1-2.0 hundredths of an inch.

In these or other embodiments, the curve as a path that is smoothly curved, continuous, and does not cross itself. In these or other embodiments, the wand comprises or consists essentially of a quartz material.

### BRIEF DESCRIPTION OF THE DRAWINGS

FIG. 1 is an isometric view of a bottom plate of an embodiment of the invention showing a channel in the bottom plate and small gas orifices.

FIG. 2 is a side view of the wand of an embodiment of the invention showing the top plate bonded to the bottom plate.

FIG. 3 is a top view of the wand of an embodiment of the invention depicting bonded top and bottom plates and a smooth, continuous channel shown in covered relief.

FIG. 4 is a top view of the wand, with bonded top and bottom plates, and a smooth continuous channel showing the direction of gas flow illustrated by vectors through the multiple small orifices in covered relief.

FIG. 5 is the view of FIG. 2 additionally showing a semiconductor wafer.

FIG. 6 is the view of FIG. 1 additionally showing a semiconductor wafer.

### DETAILED DESCRIPTION OF THE INVENTION

| Component | Reference number |
|---|---|
| Wand | 102 |
| Top Plate | 104 |
| Bottom Plate | 106 |
| Channel | 108 |
| Air Outlets | 110 |
| Underside of Bottom Plate | 112 |
| Air Inlet | 114 |
| Semiconductor wafer | 116 |

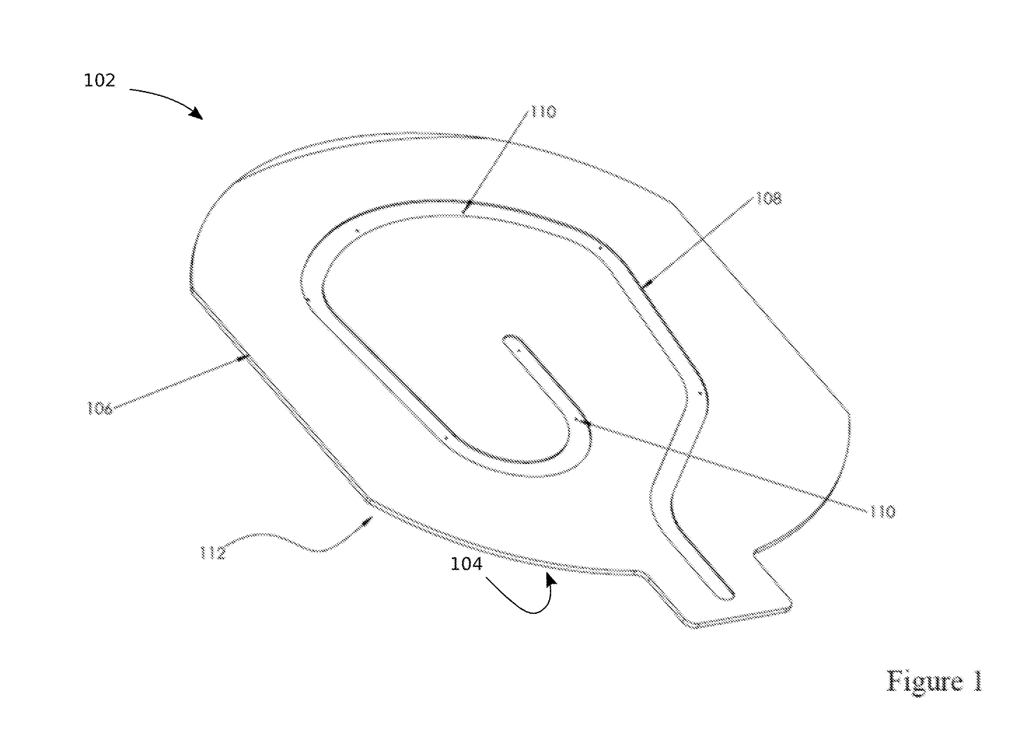

FIG. 1 shows a positive pressure Bernoulli-type wand 102 typically used in the processing of semiconductor material. In some embodiments, the device is made primarily of quartz. It has top plates 104 and bottom plates 106. The plates are joined to form or contain a working gas flow channel 108 that has a smooth, continuously curving path. FIG. 1 also shows several small openings 110, and bottom plate 106 has underside 112. Small openings 110 allow working gas to flow out of channel 108 through the bottom plate 106. Small outlet orifices should be small enough to maintain a pressure difference of P1 (inside wand)>P2 (atmosphere/air) in order to provide for sufficient mass flow rate to provide lift/suction of the wafer. Typically, the diameter of these holes is on the order of hundredths of inches to maintain an appropriate mass flow-rate.

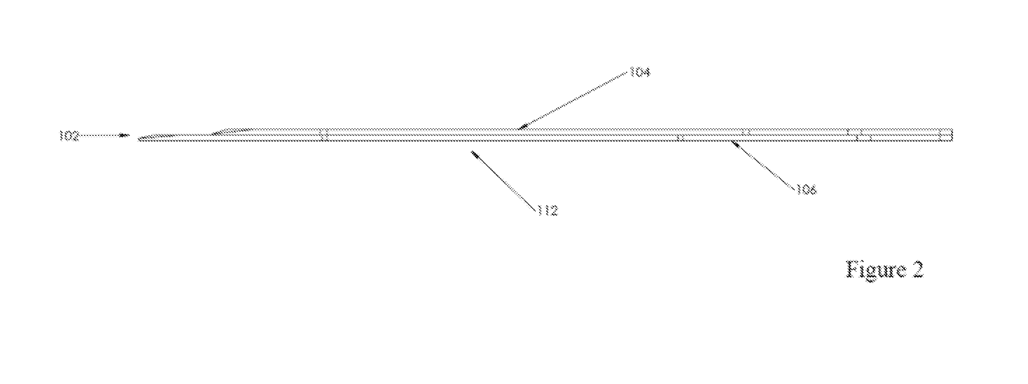

FIG. 2, also, shows top and bottom plates 104 and 106 in a bonded configuration. FIG. 2 also illustrates the underside 112 of bottom plate 106, not directly shown. In FIG. 2, small openings 110 are not shown.

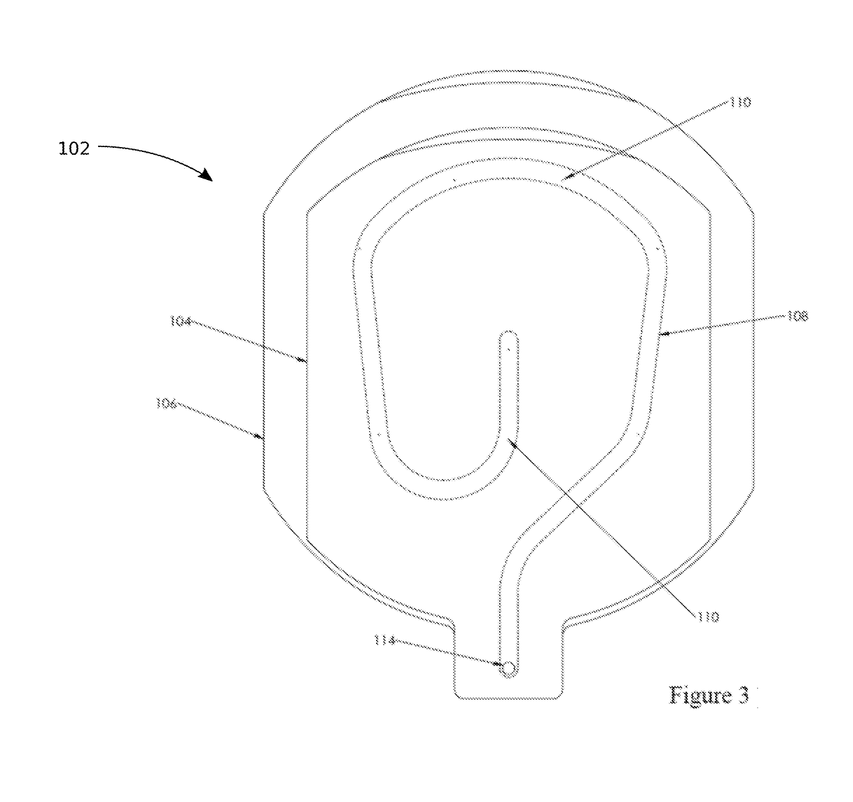

FIG. 3 shows a top view of wand 102. This view is looking down through the device. Channel 108 is shown in relief. Channel 108 is formed into or onto the surface of the bottom plate 106 such as by milling or other technique known to those of ordinary skill in the art. The surface of the bottom plate comprising channel 108 faces or bonds to top plate 104. The working gas enters channel 108 through air inlet 114. Alternatively, channel 108 is formed into or onto top plate 104 such as by milling or other technique known to those of ordinary skill in the art. In this alternative, the surface of the top plate containing channel 108 bonds to bottom plate 106. In some embodiments, channel 108 is formed into or onto both top plate 104 and bottom plate 106.

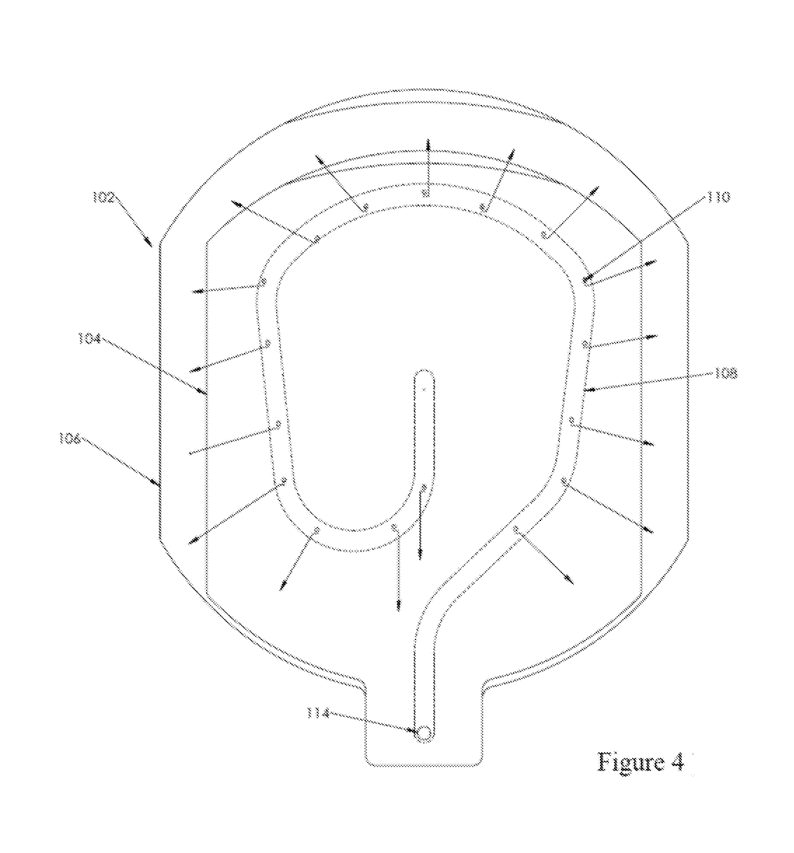

FIG. 4 shows working gas flow is illustrated by vectors. Gas flows out of small orifices 110 and generates the Bernoulli effect. The indicated gas flow through small orifices 110 in underside 112 of bottom plate 106 is down upon the upper surface of an object beneath wand 102. This flow of the working gas induces a vacuum above the surface of the object beneath wand 102. Under normal atmospheric pressure, the vacuum above the object beneath wand 102 pulls the object toward wand 102 until it comes in close contact with underside 112. The downward flow of the working gas (vectors in FIG. 4) prevents the object from contacting wand 102. This prevents damage to the object that would normally occur if the object contacted a tool.

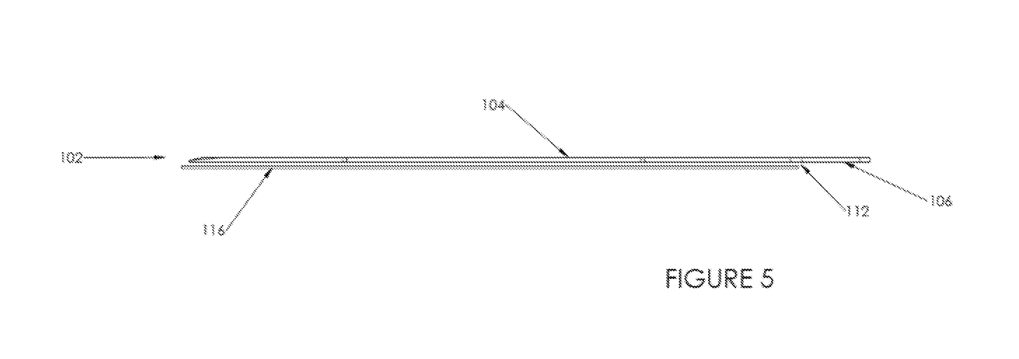

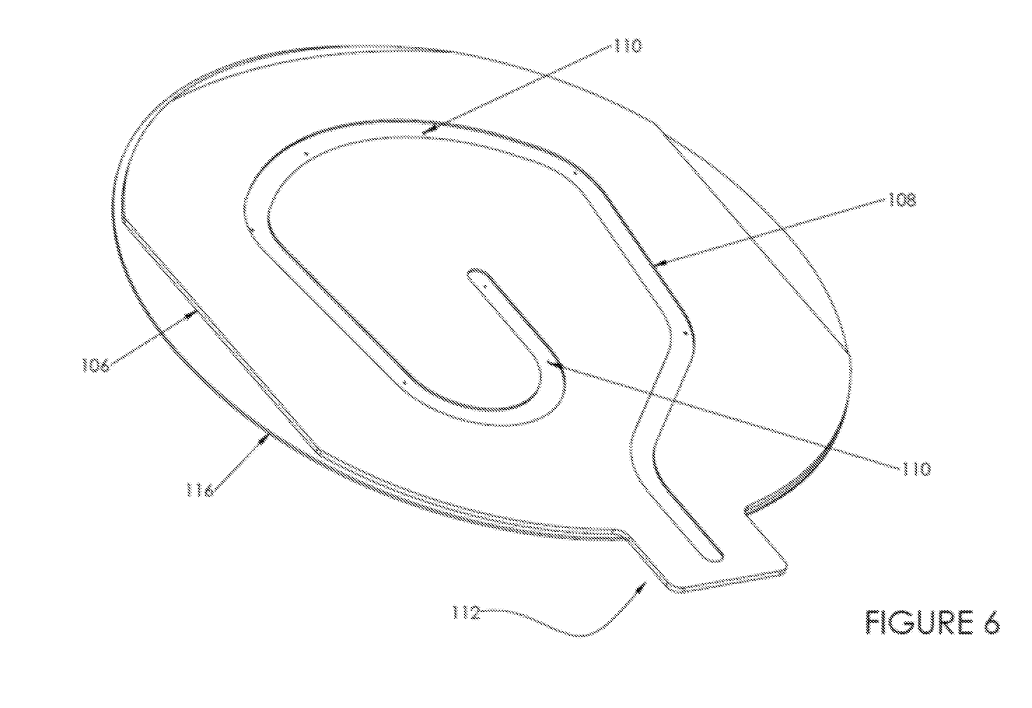

FIGS. 5 and 6 depict semiconductor 116 being manipulated by wand 102. FIG. 5 shows that semiconductor 116 approaches underside 112, but does not contact it.

Top and bottom plates 104 and 106, shown in FIG. 2 may be made of any material suited for use in the semiconductor reactor arena including; Quartz (SiO2), Silicon Carbide (SiC), Magnesium Oxide (MgO), Aluminum Oxide (Al2O3), Titanium Carbide (TiC). In some embodiments, the top and bottom plates 104 and 106 comprise quartz or consist essentially of quartz.

The plates may be joined with any adhesive known for use in the semiconductor processing field Including materials comprising graphite, alumina, silica, magnesium oxide. In some embodiments, adhesives comprise ceramic or graphite. The plates may be joined with thermally worked frit comprising or consisting essentially of quartz, such as thermally worked solid intermediary quartz, glass, related ceramic, or epoxy.

The plates may be joined using other methods commonly used to connect quartz in a heat process known to those in the semiconductor field.

In some embodiments, the joint is a bond. A bond is an adhesive, cementing material, or fusible ingredient that combines or unites top plate 104 to bottom plate 106 into a rigid unit.

The plates may be bonded using laser bonding, where the laser, such as a CO2 laser, is focused at the bond line allowing a weld seam to be created between the plates. Those of ordinary skill in the art will recognize that other bonding or heating techniques would suit this invention.

This invention uses a smooth and continuously curved channel 108, as shown in FIGS. 1, 3, and 4, within wand 102. Channel 108 does not cross back upon or intersect with itself. And channel 108 has no sharp angles or no macroscopic sharp angles, as shown in FIGS. 1, 3 and 4. This smooth and continuous curving of channel 108 reduces potential stress points, which may otherwise occur at the intersection of two channels or in the region of a step of a sidewall within a channel.

Without wishing to be bound by any theory, using a smooth continuous channel 108 allows wand 102 to be manufactured with fewer built-in stress-crack-initiation points. This may yield fewer stress cracks over time and may yield a more durable wand 102. In prior art devices, discontinuous or sharply angled changes in the channel's path can create stress-crack-initiation points. These stress points may help to create or to propagate stress fractures during gas flow.

### EXAMPLES

This wand is made in a manner common to the current manufacturing methodology of Bernoulli wands in use in the semiconductor processing industry today. Two quartz plates, a top plate and bottom plate, are made to specifications common to wand manufacture in the semiconductor field. Therefore, they are made to fit commonly used semiconductor reactors. Channel 108 is created by milling a groove into either or both plates 104 and 106 before bonding them together. In this embodiment, channel 108 is milled or bonded with a channel width of 6.35 mm and an overall length of 470 mm. Channel width and length may vary according to the overall dimensions of the wand 102. The plates are bonded together using thermally worked frit comprising or consisting essentially of quartz, glass, or related ceramic. The bonding of the two plates to each other may be done using epoxy, melted glass or quartz particles or other methods commonly used to bind quartz in a heat process known to those in semiconductor field.

The creation of the continuous curved channel groove 108 in the plates 104 and 106 may be done by milling, grinding, drilling or other common methods used in the machining of quartz. This application may be applied to one or both plates that are part of wand 102.

What is claimed is:

1. A wand comprising:
a top plate;
a bottom plate with an underside;
a plurality of gas orifices disposed in the bottom-plate underside with a diameter of 0.1-2.0 hundredths of an inch penetrating the bottom plate; and
a curved channel associated with the bottom plate and having a path.

2. The wand of claim 1 wherein the path is smoothly curved.

3. The wand of claim 2 wherein the path is continuous.

4. The wand of claim 3 wherein the path does not cross itself.

5. The wand of claim 4 comprising quartz glass.

6. The wand of claim 5 wherein the top plate or the bottom plate consist essentially of quartz.

7. The wand of claim 6 consisting essentially of quartz glass.

8. The wand of claim 2 comprising quartz glass.

9. The wand of claim 8 wherein the top plate or the bottom plate consist essentially of quartz.

10. The wand of claim 9 consisting essentially of quartz glass.

11. The wand of claim 1 wherein the path does not cross itself.

12. The wand of claim 11 comprising quartz glass.

13. The wand of claim 12 wherein the top plate or the bottom plate consist essentially of quartz.

14. The wand of claim 13 consisting essentially of quartz glass.

15. The wand of claim 1 comprising quartz glass.

16. The wand of claim 15 wherein the top plate or the bottom plate consist essentially of quartz.

17. The wand of claim 11 wherein the path is smoothly curved.

18. The wand of claim 17 wherein the path is continuous.

19. A positive pressure Bernoulli-type wand comprising:
a top plate;
a bottom plate connected to the top plate and having an underside;
a channel disposed into or onto the bottom plate following a path that does not cross itself; and
gas orifices penetrating the bottom plate from the underside into the channel.

20. A positive pressure Bernoulli-type wand comprising:
a quartz top plate;
a quartz bottom plate connected to the top plate and having an underside;
a channel disposed into or onto the bottom plate following a path that does not cross itself; and
gas orifices with a diameter of 0.1-2.0 hundredths of an inch penetrating the bottom plate from the underside into the channel.
